(19) United States
(12) Patent Application Publication
(10) Pub. No.: US 2016/0056414 A1
(43) Pub. Date: Feb. 25, 2016

(54) Thin film permeation barrier system for substrates and devices and method of making the same

(71) Applicant: Universal Display Corporation, Ewing, NJ (US)

(72) Inventors: Siddharth Harikrishna Mohan, Plainsboro, NJ (US); William E. Quinn, Whitehouse Station, NJ (US)

(21) Appl. No.: 14/464,997

(22) Filed: Aug. 21, 2014

(51) Int. Cl. H01L 51/52; H01L 51/00

(52) U.S. Cl. CPC H01L 51/5256; H01L 51/0097; H01L 51/0094; H01L 2251/5338; H01L 2251/301

(57) ABSTRACT

Thin film permeation barrier systems and techniques of fabricating the same are provided. The barrier system includes a hybrid layer, such as a layer containing SiOₓC_{y}H_{z}, and an inorganic layer.

The claimed invention was made by, on behalf of, and/or in connection with one or more of the following parties to a joint university corporation research agreement: Regents of the University of Michigan, Princeton University, The University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to organic light emitting devices (OLEDs) and similar devices, and various layers incorporated therein. More specifically, it relates to permeation barriers suitable for use with an OLED or other similar device or substrate.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

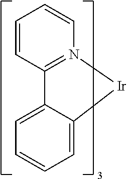

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

In an embodiment, a thin film barrier is provided that includes a first hybrid barrier layer comprising SiOₓC_{y}H_{z}, and an inorganic second barrier layer disposed immediately adjacent to the first hybrid barrier layer. The thin film barrier may include only, or may consist essentially of, the first hybrid barrier layer and the inorganic second barrier layer. The thin film barrier may be flexible, and may be used to encapsulate or otherwise protect sensitive devices such as OLEDs.

In an embodiment, a thin film barrier may be fabricated by obtaining at least one organosilicon-containing precursor, plasma depositing each of the precursors to form a barrier layer comprising SiOₓC_{y}H_{z} above a substrate, depositing an inorganic layer above the substrate and immediately adjacent to the barrier layer. The barrier layer may be deposited above or below the inorganic layer, and the combination of layers may be deposited on one or both sides of the substrate. One or more masks may be used to deposit the layers, and a single mask may be used to deposit both layers. The layers may be deposited without any masks being used.

### BRIEF DESCRIPTION OF THE DRAWINGS

FIG. 1 shows an organic light emitting device.

FIG. 2 shows an inverted organic light emitting device that does not have a separate electron transport layer.

FIG. 3A shows a cross section of a thin film permeation barrier system according to an embodiment of the present invention.

FIG. 3B shows a cross section of a thin film permeation barrier system according to an embodiment of the present invention.

FIG. 4 shows a cross section of an example substrate coated with a barrier system according to an embodiment of the present invention; FIG. 4A shows a configuration in which the barrier is coated on the top of the substrate; FIG. 4B shows a configuration in which the barrier is coated on the bottom of the substrate; and FIG. 4C shows a configuration in which the barrier is coated on both the top and bottom of the substrate

FIG. 5 shows a schematic illustration of top-down diffusion in a permeation barrier system according to an embodiment of the present invention.

FIG. 6 shows a schematic illustration of top-down and lateral diffusion in a permeation barrier system according to an embodiment of the present invention.

FIG. 7 shows a schematic illustration of top-down diffusion and horizontal incursion in an OLED encapsulated with a permeation barrier system according to an embodiment of the present invention.

FIG. 8 shows a plot of the quantity of permeated water as a function of time according to an embodiment of the present invention.

FIG. 9 shows a plot of the time for one monolayer of water to diffuse as a function of bezel width according to an embodiment of the present invention.

FIG. 10 shows a schematic cross section of an OLED on a substrate encapsulated with a permeation barrier system according to an embodiment of the present invention, in which the barrier system is deposited on top of the substrate prior to OLED growth and another barrier system is deposited on top of the OLED.

FIG. 11 shows a schematic cross section of an OLED on a substrate encapsulated with a permeation barrier system according to an embodiment of the present invention, in which the barrier system is deposited on both the top and bottom of the substrate prior to OLED growth and another barrier system is deposited on top of OLED.

FIG. 12 shows a plot of the change in stress as a function of time according to an embodiment of the present invention.

FIG. 13 shows photos of a comparative OLED device at times T=0 hours and T=24 hours.

FIG. 14 shows photos of a comparative OLED device 2 at times T=0 hours and T=96 hours.

FIG. 15 shows photos of an OLED device according to an embodiment of the present invention at T=0 hours and T=500 hours.

FIG. 16 shows photos of an OLED device according to an embodiment of the present invention at T=0 hours and T=500 hours.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

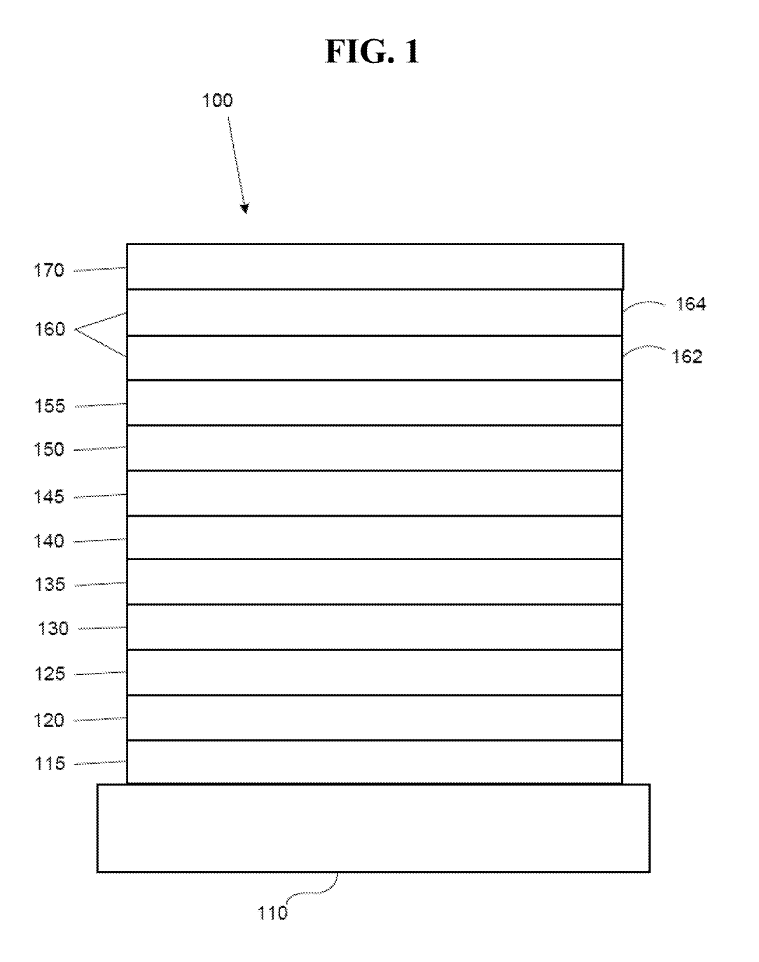

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

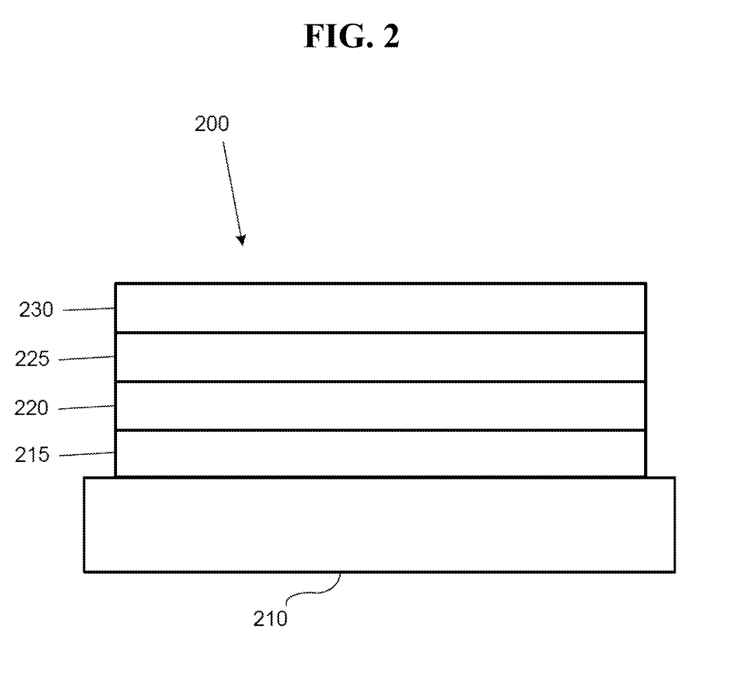

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJP. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention may be incorporated into a wide variety of consumer products, including flat panel displays, computer monitors, medical monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree C. to +80 degree C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

OLED displays and lighting panels often benefit from reliable protection from atmospheric gases, in particular moisture and oxygen. The chemically-reactive low work function metals used as electrodes often are unstable in the presence of these species, and can delaminate from the underlying organic layer. Commonly used organic emissive materials also can form non-emissive quenching species upon exposure to water. Conventionally, protection often is provided by encapsulating the OLEDs and a desiccant between two glass plates, which are sealed around the edge with an adhesive. This traditional encapsulation method makes the device rigid and hence cannot be used for encapsulating flexible OLEDs. To make OLED displays flexible and lightweight, thin flexible barrier films may be used instead of rigid glass plates.

Polymeric substrates such as poly ethylene terephthalate (PET), poly ethylene naphthalate (PEN), etc. used to fabricate flexible OLEDs may inherently have poor moisture barrier properties. For example, the water vapor transmission rate (WVTR) of 100 μm thick PET is approximately 3.9 and 17 g/m²/day at 37.8 C and 40 C, respectively. The most widely-quoted value for required water vapor transmission rate (WVTR) for an OLED lifetime of 10,000 hours is 10⁻⁶ g/m²/day. Similarly, oxygen transmission rates (OTR) for a similar lifetime have been reported as anywhere from to 10⁻⁵ cm³/m²/day to 10⁻³ cm³/m²/day (e.g., Lewis and Weaver, “Thin Film Permeation Barrier Technology for Flexible Organic Light Emitting Devices”, IEEE Journal of Selected Topics in Quantum Electronics, Vol. 10, No. 1, p. 45, January/February 2004). Further, at least one surface of the display must be protected with a barrier film that is transparent, to allow for transmission of light generated by the OLED. When coated over an OLED, it often is desirable to deposit the barrier film at or near room temperature, because high temperatures will damage the underlying OLED. Although many inorganic materials such as Si₃N₄, SiO₂, and Al₂O₃ have low permeability for atmospheric gases, fabricating transparent encapsulating barrier films from inorganic oxides and nitrides has proven difficult in the art, as they become permeable when deposited as thin films at or near room temperature. First, single inorganic barrier layers contain microscopic defects when deposited at room temperature. These defects may form pathways for permeation of atmospheric gases including water vapor, as reported by Erlat, “SiOₓ Gas Barrier Coatings on Polymer Substrates: Morphology and Gas Transport Considerations”, J. Phys. Chem. B, 1999, 103, 6047-55). Secondly, inorganic thin films (barrier layers) such as SiOₓ, SiNₓ, or SiOₓN_{y}, may develop self-relief micro-cracks once they reach a critical thickness, which ultimately may limit the permeation barrier properties. Lastly, the critical cracking strain value may limit the overall flexibility of the OLED device. The cracking strain of these single inorganic layers is a function of the thickness. For example, the cracking strain of a 100 nm ITO layer is about 1%.

Flexible thin film barriers have been previously demonstrated as encapsulants for substrates and electronics devices. U.S. Pat. Nos. 6,548,912, 6,268,695, 6,413,645, and 6,522,067 describe various arrangements of “multiple” barrier stacks and/or dyads to encapsulate moisture sensitive devices and substrates. Each barrier stack pair or “dyad” includes an inorganic material and polymer layer pair. The inorganic layer, typically a metal oxide such as Al₂O₃, which has low permeability for atmospheric gases, serves as the barrier layer. The polycrystalline Al₂O₃ is usually deposited by reactive sputtering at room temperature. These films often contain microscopic defects such as pinholes, cracks, and grain boundaries that eventually form pathways for permeation of atmospheric gases including water vapor. The polymer layer is usually a polyacrylate material, which is deposited by flash evaporation of a liquid acrylate monomer that is subsequently cured by UV radiation or an electron beam. This polymer layer may mechanically decouple the defects in the inorganic layer, as disclosed in U.S. Pat. No. 6,570,325. By using multiple dyads (often around 3 to 5 dyads, which is 6 to 10 layers), these barrier films may protect the underlying device by mechanically de-coupling the rigid inorganic layers from each other and by forcing long permeation paths on water and oxygen, so that these molecules take long times to reach the OLED. Although this method may provide a long lag time for top-down diffusion of water vapor through the dyads, it fails to address the lateral/edge diffusion of water vapor when used to directly encapsulate OLEDs. Since the polymer/decoupling layer has a high diffusion co-efficient for water vapor, a very wide edge seal is required for protection. One way to reduce the edge seal width is disclosed in U.S. Pat. No. 7,198,832, the disclosure of which is incorporated by reference in its entirety. In this method, in a given barrier stack, the area of the inorganic barrier layer is made larger than the area of the decoupling layer, i.e., the polymer layer. Subsequently, the area of the second barrier stack needs to be larger than the area of the first barrier stack and so on. By adopting this structure, the barrier layer may provide protection against lateral/edge diffusion of water vapor and oxygen.

A conventional multilayer barrier system may have disadvantages. The polymer layer/decoupling layer, typically an acrylate, may have a high diffusion coefficient for water vapor. When the conventional multilayer barrier is used to directly encapsulate an OLED, this high diffusion coefficient may result in a fundamental limit on the minimum edge width obtainable because the footprint of the inorganic barrier layer must be made larger than the area of the decoupling layer, i.e., the polymer layer. Subsequently, the footprint of the second barrier stack needs to be larger than the area of the first barrier stack and so on to obtain a good edge seal. This may require the use of multiple masks, which in turn demands frequent mask cleaning, making the overall process cumbersome and considerably increases the TAKT time. For example, U.S. Patent Pub. No. 2014/170785 describes various systems and techniques that require the use of multiple masks, resulting in a great deal of effort being devoted to managing and moving the masks during fabrication. In contrast, as described in further detail herein, embodiments of the invention may avoid such issues by using fewer masks.

Further, the edge width or bezel width is a non-usable portion of the display. It may be difficult or impossible to obtain an almost zero-edge or an edgeless display using these techniques.

Another disadvantage may be that, to obtain a high quality inorganic barrier layer, the deposition rate of the inorganic barrier layer, such as a sputtered metal oxide layer, may be kept low compared to the polymer layer. This increases the TAKT time.

Another disadvantage may occur during batch processing, in which the substrate may need to be translated multiple times (e.g., 6 to 8 times) between a sputter chamber (in vacuum) to an inert atmosphere chamber (non-vacuum) to flash evaporate the monomer layer. In web processing, multiple sputter targets and monomer sources may be required to deposit multilayers. Each of these also increases the cost and TAKT time.

In general, it may be desirable for a barrier system to satisfy several main requirements: relatively low permeability to moisture, preferably with a minimum number of layers; sufficient seal at the edge, preferably with a relatively small edge width; and relatively high flexibility.

Regarding the need for relatively low permeability, as previously described, effective encapsulation is required to prevent the degradation of OLED devices from moisture and oxygen. The barrier property of an encapsulation barrier may be measured in terms of two diffusion parameters: the permeability P=g/(cm sec atm) and the vapor transmission rate VTR=g/(m² day). The permeability P of a gas, typically water vapor or oxygen in the case of OLEDs, through a single barrier is defined as P=DS, where S (g/(cm³ atm)) is the solubility of the gas in the barrier material, and D is the diffusion coefficient of the gas in the barrier material. Solubility determines how much of the permeant can be dissolved in the film while the diffusion coefficient determines how fast the permeant can move in the film material. The transmission rates for water vapor (WVTR) and oxygen (OTR) are the measures of barrier properties of the encapsulation. They are specified at a given temperature and relative humidity for a given barrier thickness. As previously disclosed, a commonly-quoted requirement for a water vapor transmission rate for an OLED shelf lifetime of 10000 hours (50% active area shrinkage) is 10⁻⁶ g/m²/day. Similarly, the required oxygen transmission rate (OTR) for similar lifetimes ranges from 10⁻⁵ cm³/m²/day to 10⁻³ cm³/m²/day. A more direct way to specify the lifetime of OLED devices is to use lifetime at accelerated environmental test conditions (high temperature, high relative humidity). Widely used industrial OLED shelf lifetime requirements depend on the specific application (display or lighting), and are specified as less than 5% active area shrinkage after either a) 240 hours at 85 C, 85% relative humidity (10 days) or b) 500 hours at 85 C, 85% relative humidity (˜3 weeks).

Regarding the desired edge properties, it typically is desirable for a barrier system to protect the OLED against lateral diffusion of moisture and oxygen. Preferably, a barrier film should provide a good edge seal with minimum edge width/bezel requirement. The minimum bezel width depends on specific applications and or manufacturing tolerances, but typically the bezel width can range from 0.1 mm to 5 mm.

Generally, it may be desired that a barrier system should be sufficiently flexible to withstand about a 10,000-cycle flex test over a 1.27 cm radius when used for encapsulation of flexible substrates and devices.

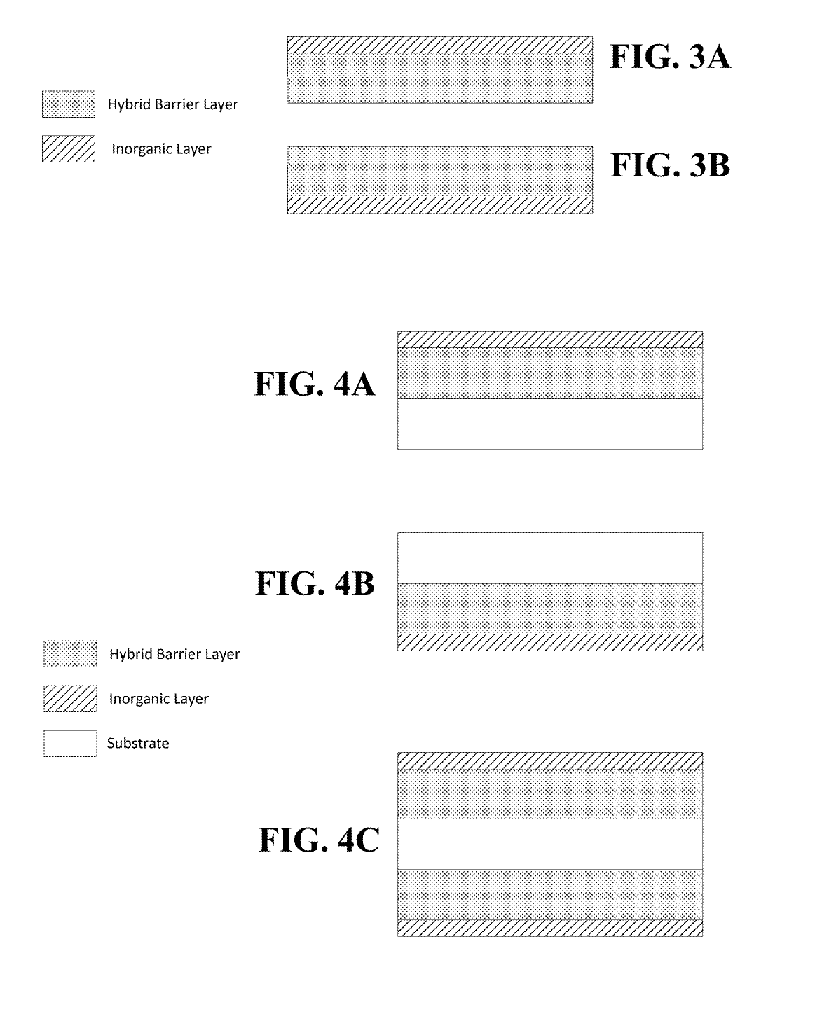

Embodiments of the present invention provide fabrication techniques and thin film permeation barrier systems for substrates and devices that may address these shortcomings of previous systems. A permeation barrier system as disclosed herein may include at least one hybrid barrier layer and one inorganic shield layer. The hybrid barrier layer may include, for example, SiOₓC_{y}H_{z}, as described in further detail herein. The thin film barrier structure may be deposited so that the inorganic layer “shields” the hybrid barrier layer from environmental test conditions. The hybrid barrier layer may be disposed between the inorganic layer and the substrate over which the thin film permeation barrier is deposited, or the inorganic layer may be disposed between the hybrid barrier layer and the substrate. FIG. 3A shows an example permeation barrier as disclosed herein in which the inorganic layer is disposed over the hybrid barrier. Similarly, FIG. 3B shows an example permeation barrier as disclosed herein in which the hybrid barrier is disposed over the inorganic layer. The hybrid barrier layer and the inorganic layer may be disposed immediately adjacent to one another, i.e., such that they are in direct physical contact. In some embodiments, the thin film permeation barrier may include only or essentially only the hybrid barrier and the inorganic layer. As described in further detail herein, a thin film permeation barrier also may be relatively flexible, allowing for the barrier layer to be used to encapsulate flexible devices such as flexible OLEDs as disclosed herein.

As a more specific example, when coating a moisture sensitive electronic device such as an OLED or the backside of a substrate, the hybrid barrier layer may be first disposed over the coating surface. The second inorganic shield layer may then be deposited over the first hybrid barrier layer. FIG. 4A shows an example of such an arrangement, in which the hybrid barrier layer is disposed over the substrate and the inorganic shield layer is disposed over the hybrid barrier layer. Alternatively or in addition, when coating the front side of the substrates such as for a bottom-emitting device, a hybrid barrier layer may be disposed first over the coating surface. The second inorganic barrier layer then may be deposited over the first hybrid barrier layer as shown in FIG. 4B. For the bottom emitting device, the barrier system may be deposited before the organic layers, or after the organic device deposition is completed. A combination of these arrangements can also be used, as shown in FIG. 4C. In each configuration, the inorganic layer(s) “shields” the hybrid barrier layer(s) from the external environment. Thus the inorganic layer generally faces the environment, and the hybrid barrier layer is closer to or adjacent to the device; i.e., the hybrid layer typically is closer to the substrate than the inorganic shield layer in these configurations.

In an embodiment, the hybrid barrier layer may be grown by plasma enhanced chemical vapor deposition (PECVD) of an organic precursor with a reactive gas such as oxygen, e.g., HMDSO/O₂. An example of a barrier coating process is described in U.S. Pat. No. 7,968,146, the disclosure of which is incorporated by reference in its entirety. Such a barrier film typically is relatively highly impermeable yet flexible. The material is a hybrid of inorganic SiO₂ and polymeric silicone, and may be deposited at room temperature. The barrier film has permeation and optical properties of glass, but with a partial polymer character that gives thin barrier films flexibility. At room temperature, a layer of this hybrid material is free of microcracks when deposited approximately thicker than 100 nm. Further, the deposition process and the film composition can be tuned to grow thick layers (>10 microns) of SiOₓC_{y}H_{z} without micro-cracks. Thus, embodiments of the invention may include a hybrid barrier that includes SiOₓC_{y}H_{z}, with relative compositions equivalent to 1≦x<2, 0.001≦y≦1, and 0.001≦z≦1. Such a barrier may provide relatively low permeability to moisture and oxygen, particle coverage via conformal coating by PECVD, a relatively high edge seal with minimal edge/bezel requirement, transparency, and flexibility. The deposition process is relatively cost-effective with somewhat average TAKT time. In some embodiments, the hybrid barrier layer may be fabricated using one or more precursors, all of which may be deposited in a single plasma deposition or similar process. Example precursors include hexamethyl disiloxane (HMDSO); tetrathylorthosilicate (TEOS); methylsilane; dimethylsilane; vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene; dimethylphenylsilane; diphenylmethylsilane; tetraethylortho silicate; dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane; hexamethyldisilazane; divinyltetramethyldisilizane; hexamethylcyclotrisilazane; dimethylbis(Nmethylacetamido)silane; dimethylbis-(N-ethylacetamido)silane; methylvinylbis(Nmethylacetamido)silane; methylvinylbis(N-butylacetamido)silane; methyltris(Nphenylacetamido)silane; vinyltris(N-ethylacetamido)silane; tetrakis(N-methylacetamido)silane; diphenylbis(diethylaminoxy)silane; and methyltris(diethylaminoxy)silane. In an embodiment, a permeation barrier system as disclosed herein may be used to encapsulate an environmentally-sensitive device, such as an OLED. The environmentally sensitive display or lighting device such as an OLED may be placed or fabricated on the substrate by deposition, such as vacuum deposition. A hybrid barrier layer may be directly disposed over the OLED, as shown in FIG. 7. The footprint of the hybrid barrier layer may extend beyond the edge of the OLED by a bezel width w. The bezel width w may be 0.001-50 mm, and commonly may be in the range of 0.01-10 mm. An inorganic shield layer may be disposed over the hybrid barrier layer.

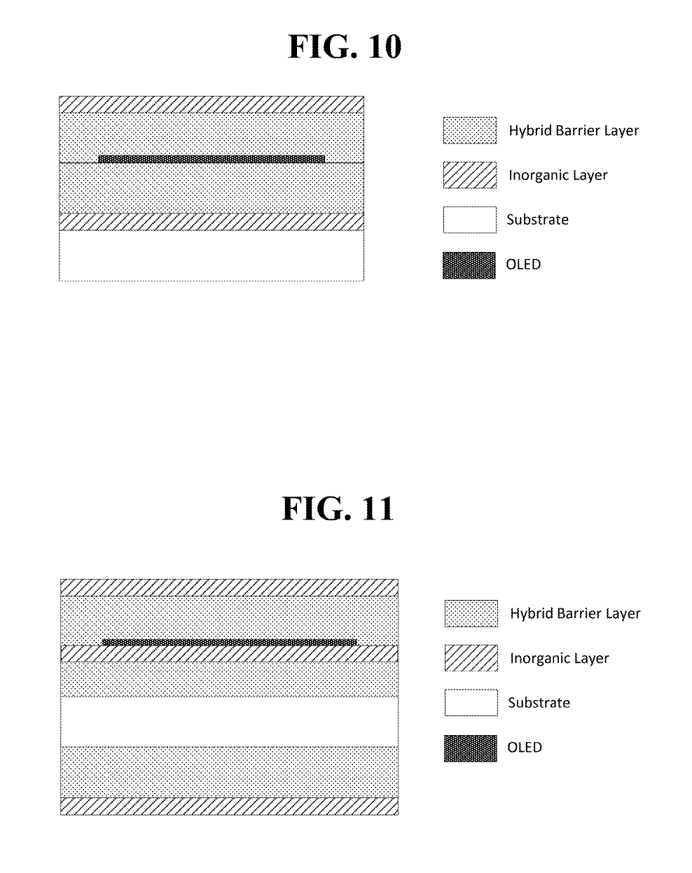

In some embodiments, polymeric substrates such as PET, PEN, or the like may be used. In such a configuration, schematic structures such as those shown in FIG. 10 and FIG. 11 may be adopted to provide adequate moisture protection. In FIG. 10, the substrate is coated with the permeation barrier system on the top side prior to OLED growth. The OLED may be subsequently encapsulated with the permeation barrier system on top. In FIG. 11, the substrate is coated with the permeation barrier system on both the top and side, and the OLED is encapsulated with the permeation barrier system on top. More generally, such structures may be used with any substrate that requires or benefits from a permeation barrier layer.

In embodiments of the invention, the inorganic shield layer may be partially or entirely transparent or opaque, depending on the expected design and application of the display device. It may be preferable that the inorganic shield layer is relatively dense and does not have a porous/columnar structure. Preferred materials include, but are not limited to metals, metal oxides, metal nitrides, metal oxynitrides, metal carbides, metal oxyborides and combinations thereof. Suitable metals include aluminum, titanium, indium, tin, tantalum, gold, zirconium, niobium, hafnium, yttrium, nickel, tungsten, chromium, zinc and combinations thereof. Suitable metal oxides include silicon oxide, aluminum oxide, indium oxide, tin oxide, zinc oxide, indium tin oxide, indium zinc oxide, aluminum zinc oxide, tantalum oxide, zirconium oxide, niobium oxide, molybdenum oxide and combinations thereof. Suitable metal nitrides include silicon nitride, aluminum nitride, boron nitride and combinations thereof. Suitable metal oxynitrides include aluminum oxynitride, silicon oxynitride, boron oxynitride and combinations thereof. Suitable metal carbides include tungsten carbide, boron carbide, silicon carbide and combinations thereof. Suitable metal oxyborides include zirconium oxyboride, titanium oxyboride and combinations thereof.

In an embodiment, the inorganic shield layer may be fabricated by vacuum deposition techniques, such as sputtering, chemical vapor deposition, evaporation, sublimation, atomic layer deposition (ALD), plasma enhanced chemical vapor deposition (PECVD), plasma enhanced thermal evaporation, plasma assisted atomic layer deposition, and combinations thereof.

In embodiments, the inorganic layer may include a single layer or multiple layers. In addition, each of the layers themselves can made from a single material or different materials. For example, if the materials are deposited by sputtering, sputtering targets of different compositions may be used to fabricate the inorganic layer. Alternatively, two targets of the same composition may be used with different reactive gases. As another example, different types of deposition sources may be used.

In embodiments, the inorganic layer may be amorphous or polycrystalline. For example, one or more thin films of indium zinc oxide deposited by reactive sputtering from an indium zinc oxide target with oxygen reactive gas may be used, which typically are amorphous. As another example, one or more thin films of Aluminum oxide deposited by reactive sputtering from an aluminum target with oxygen reactive gas may be used, which typically are polycrystalline. Nanolaminates that include alternate thin stacks of zinc oxide and aluminum oxide can also be used for inorganic layers. For example, if the thin films are deposited by atomic layer deposition, alternate thin stacks of ZnO/Al₂O₃ may be used.

The inorganic layer may be any suitable thickness. For example, it may be between 2-20,000 nm, 5-1000 nm, or any value therein, inclusive.

Permeation barrier systems as disclosed herein may provide several advantages over conventional barriers. The use of a relatively low number of layers in the permeation barrier may provide relatively very low permeation to water vapor and oxygen. For example, in barrier systems as disclosed herein, water vapor or oxygen from the ambient environment must permeate through both the inorganic layer and the hybrid barrier layer to reach the moisture sensitive element. As previously described, the inorganic layer may “shield” the hybrid barrier layer from environmental conditions. That is, permeation occurs first through the inorganic layer.

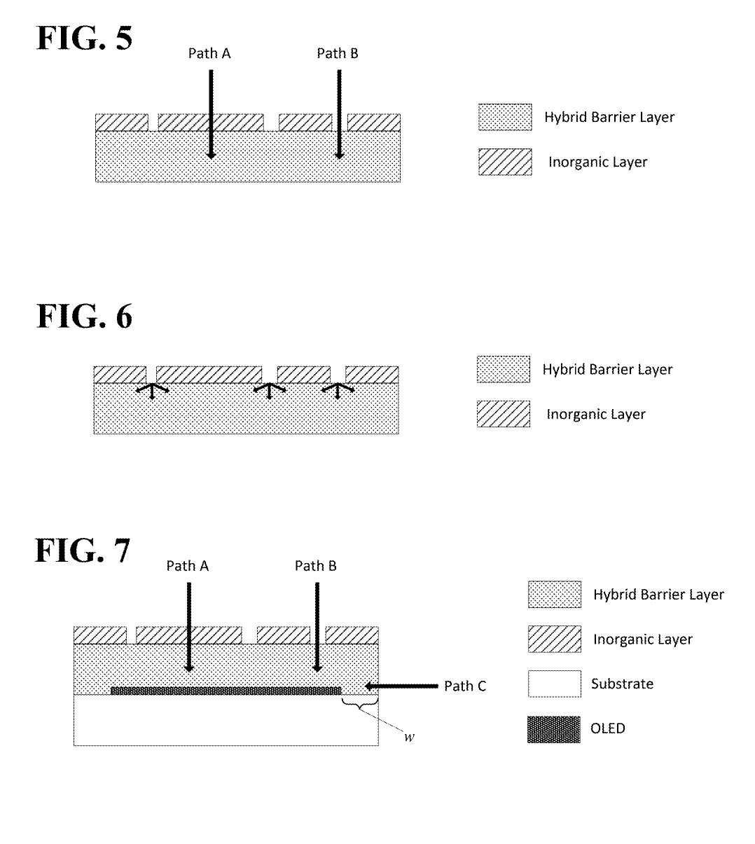

FIG. 5 shows a schematic representation of permeation through a barrier system as disclosed herein. Permeation may occur, for example, through Path A and Path B. Path A is represents intrinsic permeation through the bulk of the shield layer, while Path B represents permeation occurring through pin holes or defects in the inorganic layer. The rate of water vapor or oxygen permeation in the inorganic barrier layer, however, is not inversely proportional to the layer thickness due to a combination of surface defects, pinholes, cracking, and columnar growth in thicker films. For example, “defect-dominated” mechanisms have been cited to explain gas permeation in thin-film systems, such as described in Chatham, “Oxygen diffusion barrier properties of transparent oxide coatings on polymeric substrates”, Surface and Coatings Technology 78 (1996), p. 1-9. Under environmental test conditions, the flux of water vapor arriving at the inorganic shield layer/hybrid barrier layer interface may be dominated by permeation through Path B, which is a function of the defect size and density. These “localized” water molecules then may permeate three-dimensionally through the hybrid barrier layer, as shown schematically in FIG. 6, with the assumption that the layer is free of defects. The model may be similar to a pin hole model as proposed by Prins et. al:

$$J = - D \frac{{A}_{d}}{{A}_{t}} \cdot \frac{Δ c}{H} ( 1 + \frac{1.18 H}{r 0} )$$

(“Theory of Permeation Through Metal Coated Polymer Films”, 184th National meeting of American Chemical Society, Sep. 7-12, 1958, Vol. 63, p.716) where J is the flux of water vapor diffusing through the hybrid barrier, A_{d} is the area of the defect, Aₜ is the total area, Δc is the concentration difference, H is the hybrid barrier thickness, and r0 is the average radius of the defect in the inorganic shield layer.
In comparison to a single hybrid layer, the flux is reduced by a factor of

$$\frac{{A}_{d}}{{A}_{t}}$$

due to the inorganic layer. The flux may be reduced further by decreasing the diffusion co-efficient D of the hybrid layer. In some embodiments, the properties of the hybrid barrier layer, such as a SiOₓC_{y}H_{z} layer as previously described, may be tuned by use of different PECVD process parameters to offer a low diffusion coefficient to water vapor and oxygen. For example, an effective diffusion coefficient D of water vapor ranging from 10⁻⁹ cm²/sec to 10⁻¹⁷ cm²/sec at 38 C may be achieved. Notably, this may be preferred to a conventional multilayer barrier system in which the decoupling layer is a polymer layer having a high diffusion coefficient for water vapor and oxygen. For example, the diffusion coefficient of water vapor for most acrylic polymers is Dₚ˜4×10⁻⁹ cm²/sec to 8.5×10⁻⁹ cm²/sec at 38 C. Changes in Dₚ may have relatively minor effects on the steady-state flux and lag times until D is less than 10⁻¹⁰ cm²/s. Such a level of the diffusion coefficient may be unachievable with conventional polymeric thin films.
Another advantage in comparison to conventional multilayer barrier systems may be that the hybrid layer may be fabricated thicker without introducing micro cracks in the layer. This may increase the lag time, because the lag time is directly proportional to the square of the thickness. The lag time tₜ given by:

$${t}_{t} = \frac{{H}^{2}}{6 D}$$

where H is the thickness of the hybrid barrier and D is diffusion coefficient. Thus it is possible to obtain ultralow permeation by implementing just 2 layers, unlike the conventional multilayer barrier where a minimum of 4 to 6 layers are required to encapsulate a highly sensitive device such as an OLED.

As previously described, embodiments of the invention may provide a relatively strong edge seal with a relatively small minimum bezel. As previously described, the hybrid barrier layer may be disposed over the OLED. Because the layer may be deposited over the OLED surface, the minimum bezel width may be governed by the time taken for water vapor permeation in this layer. Referring to FIG. 7, the footprint of the hybrid barrier layer extends beyond the edge of the OLED display by a bezel width w. To provide an acceptable edge seal, the rate of ingress of water vapor in the horizontal direction along Path C is considered. The flux of water molecules diffusing is proportional to the bulk diffusion coefficient D of water in the barrier layer, neglecting interfacial effects.

Because OLEDs are highly sensitive to chemical attack by water, a realistic but strict requirement may be that, during the entire lifetime of the protected OLED, one monolayer of water molecules reaches the surface of the OLED near the edge. For a given diffusion co-efficient D, solubility S, and bezel width w, it is possible to calculate the quantity of permeated water reaching the edge of the OLED. As described in further detail below, it can be shown that for a typical configuration, 1 monolayer of water reaches the OLED edge in about 1463 hours. Thus, a bezel width as small as 0.1 mm may be achieved for a target lifetime of 1000 hours or more at 85 C, 85% relative humidity. As described herein, other bezel sizes may be achieved for different target lifetimes, deposition parameters, materials, and the like. For example, bezel widths from 0.1 to 5 mm may be achieved with minimum permeability of 9.0×10⁻¹⁵ to 1.1×10⁻¹¹ g/cm/sec at 85 C and 85% relative humidity, respectively.

The thickness, morphology, adhesion strength and built-in stress of the inorganic shield layer can influence the overall flexibility. As previously described, the properties of the hybrid barrier layer can be tuned by PECVD process parameters to meet flexibility requirements. Similarly, it may be preferred to deposit relatively very thin inorganic layers, such as inorganic layers of not more than about 100 nm, to achieve a desired flexibility of the complete barrier system.

In some embodiments, a barrier system as disclosed herein, including a hybrid barrier layer and an inorganic layer, may be deposited using relatively low-temperature fabrication techniques. For example, the hybrid barrier layer may be deposited by PECVD at low temperature, i.e., not more than 100 C. The inorganic shield layer may be deposited by any vacuum deposition process with the substrate at ambient temperature. Vacuum deposition processes may include, but are not limited to sputtering, chemical vapor deposition, thermal evaporation, e-beam evaporation, sublimation, atomic layer deposition (ALD), plasma enhanced chemical vapor deposition (PECVD), plasma enhanced thermal evaporation, plasma assisted atomic layer deposition, and combinations thereof. Thus, the layers in the barrier system may be deposited at temperatures lower than the glass transition temperature of the organic materials.

In some embodiments, a thin film barrier system as disclosed herein may be fabricated without the use of a mask, or using a single self-aligned masking process. For example, when used for direct encapsulation of OLEDs, the hybrid barrier layer may be disposed over the OLED through a shadow mask. The second inorganic shield layer then may be deposited over the first hybrid barrier layer through the same self-aligned shadow mask. As previously described, such a system may allow for relatively very small bezel widths. If the water vapor diffusion coefficient of the hybrid barrier is sufficiently low, for example, on the order of 10⁻¹⁴ cm²/sec or less, a near bezel-less or edgeless OLED device may be fabricated. In contrast, when a conventional multilayer barrier is used to directly encapsulate OLEDs, the high diffusion coefficient typically results in a fundamental limit on the minimum edge width obtainable. Further, the footprint of the inorganic barrier layer is made larger than the area of the decoupling layer, i.e., the polymer layer. Subsequently, the footprint of the second barrier stack needs to be larger than the area of the first barrier stack to obtain a good edge seal. Such a configuration requires the use of multiple masks, which in turn requires frequent mask changes and cleaning, making the overall process relatively cumbersome, lengthy, and costly.

In some embodiments, a thin film barrier as disclosed herein may be fabricated using only a two-step, all vacuum process. That is, the thin film barrier may be fabricated using one process to deposit the hybrid barrier layer and a second to deposit the inorganic layer, each of which may be performed under vacuum. Such a technique may significantly reduce transfer and masking times in comparison to other barrier fabrication techniques.

Experimental and Simulation Results

As previously described, a realistic but very demanding requirement is that during the entire lifetime of a protected OLED or similar device, one monolayer of water molecules reaches the surface of the OLED near the edge. For a given diffusion co-efficient D, solubility S, and bezel width w, it is possible to calculate the quantity of permeated water reaching the edge of the OLED. The surface concentration of water reaching the edge of the OLED is obtained solving Fick's second law of diffusion as it applied to 2 or 3 dimensional systems:

$$\frac{\partial C}{\partial t} = D {∇}^{2} C$$

where C is the concentration of dissolved water, D is the diffusion coefficient, and t is the time. Solutions were obtained by solving the equation with finite element methods, using COMSOL and MATLAB, for the following boundary conditions: the edge surface of the hybrid barrier layer exposed to the environment has a constant concentration of dissolved water equal to solubility S determined by test temperature and humidity; and the hybrid barrier layer disposed over the OLED has zero water concentration as the OLED absorbs the water.

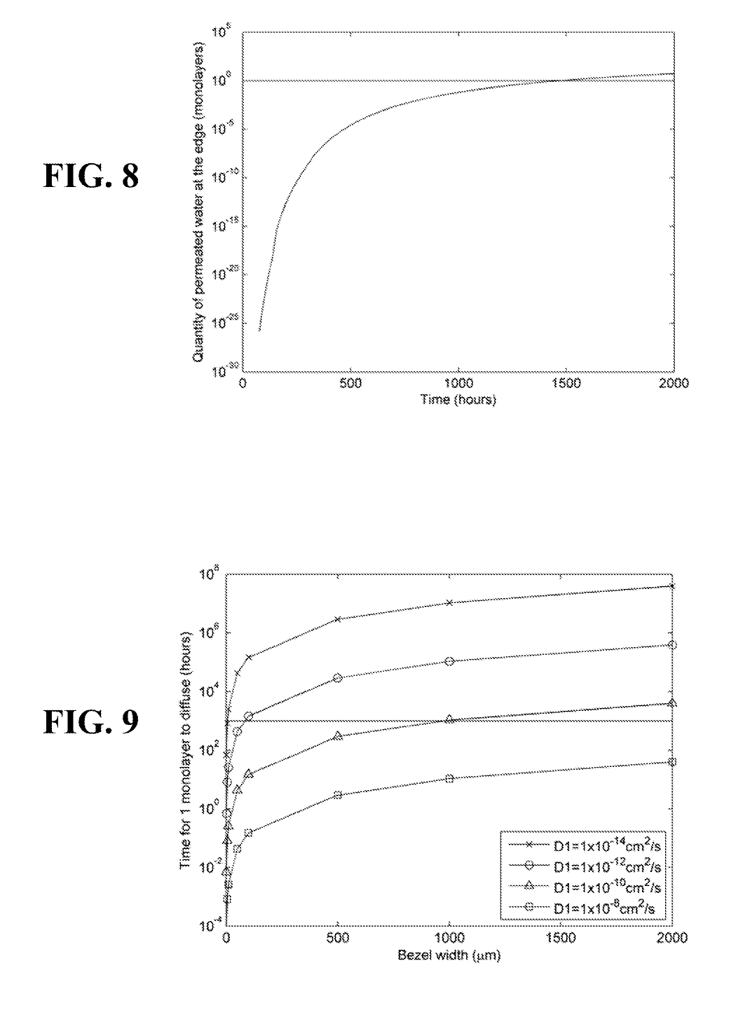

FIG. 8 shows a plot of the quantity of permeated water in monolayers as a function of time at 85 C, 85% RH for D=1×10⁻¹² cm²/sec, S=3 mg/cm³ (P=3×10⁻¹⁵ g/cm·sec) and w=100 um, with a 1000 nm thick hybrid barrier layer. As shown, 1 monolayer of water reaches the OLED edge in approximately 1463 hours. Thus, if the target shelf lifetime is 1000 hours at 85 C, 85% RH, a bezel width as small as 100 μm or 0.1 mm can provide a good edge seal. The partial pressure of water at 85 C, 85% RH is 0.485 atm, and the units of solubility and permeability are specified in mg/cm³ and g/(cm·sec) as the model accounts for the partial pressure change. All of the above simulations were performed with S=3 mg/cm³ and a barrier layer 1 μm. Reported P, D, and S values are at 85 C, 85% RH.

Similarly, time taken for 1 monolayer of water to diffuse through a given bezel width for different values of diffusion coefficients was simulated. FIG. 9 shows a plot of the time for one monolayer to diffuse as a function of bezel width. As shown, as the diffusion coefficient increases, a larger bezel width is required. For example, for a diffusion co-efficient of D=1×10⁻¹⁰ cm²/sec, a bezel width of 1 mm can provide a shelf life of 1000 hours. Thus, if a bezel width is fixed according to manufacturing tolerances at 1 mm, a target shelf lifetime of 500 hours can be achieved if the diffusion co-efficient is on the order of less than 2×10⁻¹⁰ cm²/sec. Simulations were performed to obtain the minimum desired diffusion coefficient and permeability to meet a target shelf life. The table below provides the minimum required permeability of hybrid barrier layer for a given bezel width to meet 500 hours at 85 C, 85% RH.

| | Minimum required permeability |
|---|---|
| Bezel width (mm) | at 85 C., 85% RH (g/cm · sec) |
| 0.1 | 9.0 × 10⁻¹⁵ |
| 0.5 | 1.7 × 10⁻¹³ |
| 1 | 5.8 × 10⁻¹³ |
| 2 | 2.0 × 10⁻¹² |
| 3 | 4.2 × 10⁻¹² |
| 4 | 7.1 × 10⁻¹² |
| 5 | 1.1 × 10⁻¹¹ |

The performance of a thin film permeation barrier system as disclosed herein was verified experimentally. In all the experiments, the hybrid barrier layer SiOₓC_{y}H_{z} was grown by plasma enhanced chemical vapor deposition (PECVD) of an organic precursor with a reactive gas such as oxygen; eg: HMDSO/O₂. To prove the versatility of the thin film permeation barrier, several inorganic barrier layers were deposited by various techniques, including Indium Zinc Oxide (IZO) by DC magnetron reactive sputtering, Titanium by e-beam evaporation.

The average stress of the permeation barrier structure may be calculated using the Stoney equation:

$$σ = \frac{{E}_{W}}{6 R} \frac{{h}_{s}^{2}}{H}$$

in which R is the bending radius, E_{W} is the wafer elastic constant, hₛ is the substrate thickness, and H is the barrier film thickness. When a single layer hybrid barrier layer is exposed to water, H₂O diffuses into the film. If the layer is deposited on a rigid substrate such as a silicon wafer or a rigid glass, the barrier tends to expand resulting in an increase in compressive stress. The change in compressive stress is proportional to the concentration C of dissolved water in the hybrid barrier:

Δσ∝∫C(x)·dx(0<x<H).

Thus a good permeation barrier should have a minimal change in the overall compressive stress during accelerated test conditions (high temperature, high relative humidity). In some embodiments, the hybrid barrier properties may be tuned by changing the deposition parameters as disclosed herein, so as to have a more polymer-like character, similar to a decoupling layer in a multilayer barrier stack, or a more inorganic-like character. Typically, polymer like films are poor barriers, have a higher diffusion coefficient to water, and show rapid stress change under accelerated test conditions.

To perform stress change experiments, bare 2″ Si wafers were used as substrates. A 500 nm hybrid barrier layer was deposited on each of three wafers, (A through C) by PECVD. 20 nm thick inorganic barrier layers were subsequently deposited over the hybrid barrier layer.

The permeation barrier structures are summarized below:

| Film | Barrier structure | Deposition process |
|---|---|---|
| A | 500 nm SiOₓC_{y}H_{z} | PECVD |
| B | 500 nm SiOₓC_{y}H_{z}/20 nm IZO | PECVD/Sputtering |
| C | 500 nm SiOₓC_{y}H_{z}/20 nm Ti | PECVD/e-beam evaporation |

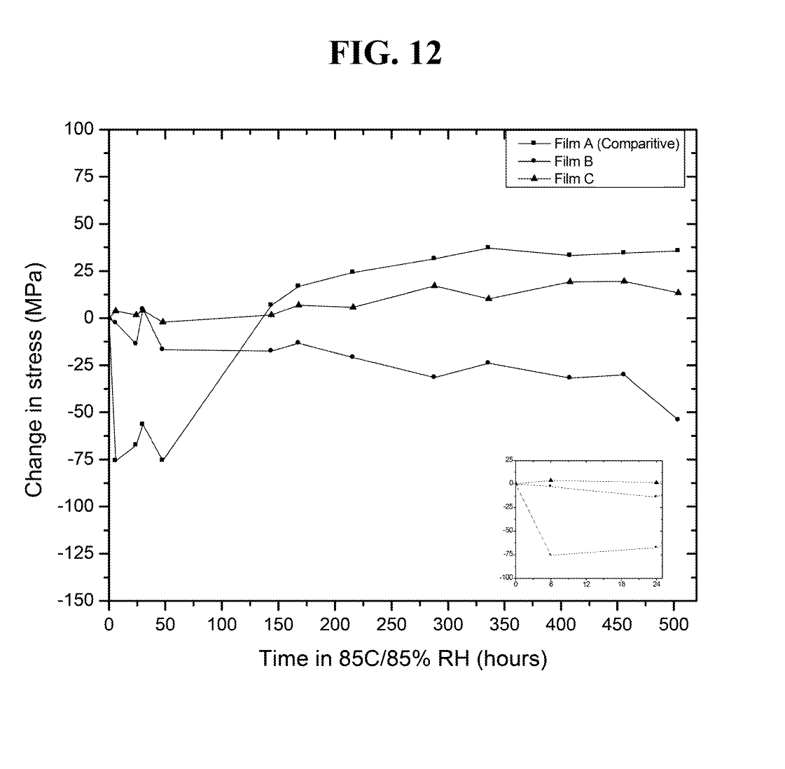

The average stress of the samples was monitored at 85 C, 85% relative humidity (RH) over time. FIG. 12 shows a plot of the change in stress as a function of time at 85 C/85% RH. The inset shows the same for the first 24 hours of the test. As shown, the stress of a single hybrid barrier (film A) changes rapidly by −75.7 MPa (compressive) within 6 hours in 85 C, 85% RH. When film A is exposed to water, H₂O diffuses into the film, causing it to expand and resulting in an increase in compressive stress. The change in compressive stress (i.e., a more negative value) is directly related to the concentration of dissolved water in the barrier. As mentioned before, the properties of this layer has been altered to deposit a polymer-like film, which is a relatively poor barrier. The stress change of such a polymer-like film can occur very rapidly, for example, in two hours or less. The change in stress for each of films B and C is negligible even after 504 hours. Further, the stress changes to its maximum value of −54 MPa (compressive) after 504 hours for Film B, and +19 MPa for Film C after 456 hours. This relatively low rate of stress change is in agreement with the theory that the inorganic layer “shields” the hybrid layer. Under environmental test conditions, the flux of water vapor arriving at the inorganic shield layer/hybrid barrier layer interface is dominated by defect size and density in the inorganic layer. These “localized” water molecules then permeate three dimensionally through the hybrid barrier layer.

To test encapsulation of OLEDs, transparent OLED devices with an active area of 2 mm² with moisture sensitive Mg:Ag cathodes were grown on glass substrates and subsequently encapsulated with thin film barriers as listed below:

| Device | Barrier structure | Deposition process | Comments |
|---|---|---|---|
| 1 | 20 nm | Sputtering/Spin | Comparative |
| | IZO/2500 nm | coating + UV curing | |
| | acrylate | | |
| 2 | 2500 nm | PECVD | Comparative |
| | SiOₓC_{y}H_{z} | | |
| 3 | 2500 nm | PECVD/Sputtering | Inventive |
| | SiOₓC_{y}H_{z}/ | | |
| | 20 nm IZO | | |
| 4 | 2500 nm | PECVD/e-beam | Inventive |
| | SiOₓC_{y}H_{z}/ | evaporation | |
| | 20 nm Ti | | |

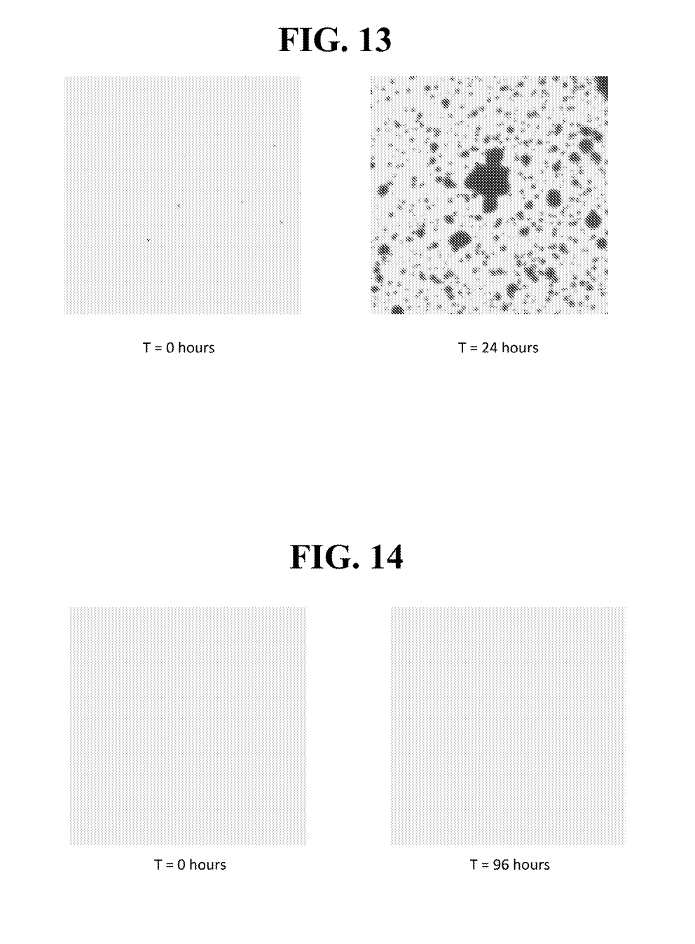

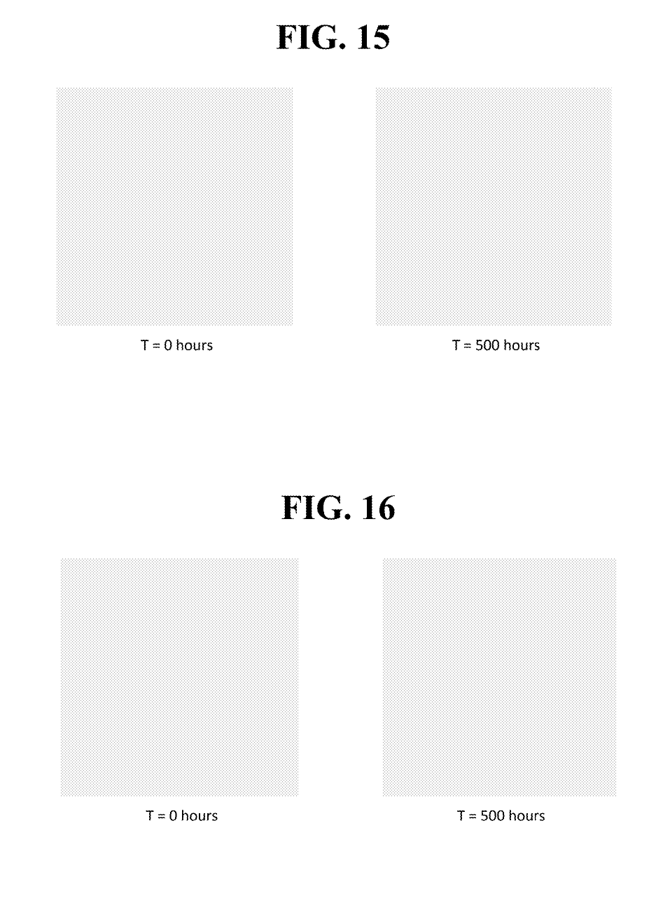

The devices were then coated with a scratch protective polymer layer, which is considered a relatively poor barrier. The devices were monitored at 85 C, 85% relative humidity (RH) over time. FIGS. 13-16 show photos of the OLED devices before and after ageing in 85 C/85% RH. The first comparative device, Device 1 (20 nm IZO+2500 nm acrylate) showed numerous dark spot growths after 24 hours, as shown in FIG. 13. This is most likely due water vapor diffusion through pin holes or other defects in the IZO layer. The active area in this device shrank by more than 1% within 24 hours. The second comparative device, Device 2 (2500 nm SiOₓC_{y}H_{z}) was defect free and lit uniformly until 96 hours, after which it catastrophically failed to emit after 100 hours, as shown in FIG. 14. This is likely due to complete oxidation of the Mg:Ag cathode due to bulk permeation of water vapor through the barrier. Device 3 (2500 nm SiOₓC_{y}H_{z}/20 nm IZO), fabricated according to an embodiment disclosed herein, remained intact even after 500 hours and showed no signs of dark spot growth, as shown in FIG. 15. Device 4 (2500 nm SiOₓC_{y}H_{z}/20 nm Ti), fabricated according to an embodiment disclosed herein, behaved similarly and showed no signs of dark spot growth, as shown in FIG. 16. Thus, devices according to embodiments disclosed herein were found to show no loss of active area after 500 hours at 85 C, 85% RH.

To test the flexibility of devices as disclosed herein, 2″×3″ of 50 μm thick PEN sheets were coated with a thin film permeation barrier structure as disclosed herein. The flexibility was tested by rolling the barrier coated PEN over a 1.27 cm radius for 10,000 cycles. The barrier may be deemed flexible if this test is passed without any cracks. The flexibility test results of the various permeation barrier structures are listed in the table below:

| Substrate | Barrier structure | Flex Test (10,000 cycles) |
|---|---|---|
| PEN A | 2500 nm SiOₓC_{y}H_{z}/20 nm IZO | Pass |
| PEN B | 2500 nm SiOₓC_{y}H_{z}/20 nm Ti | Pass |
| PEN C | 2500 nm SiOₓC_{y}H_{z}/5 nm | Pass |
| | Ti/15 nm Au | |

As shown, it was found that the devices as disclosed herein were able to pass the test without exhibiting cracks.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A thin film barrier comprising:
a first hybrid barrier layer comprising SiOₓC_{y}H_{z}, wherein 1≦x<2, 0.001≦y≦1, and 0.001≦z≦1; and
an inorganic second barrier layer disposed immediately adjacent to the first hybrid barrier layer.

2. The thin film barrier of claim 1, wherein the thin film barrier consists essentially of the first hybrid barrier layer and the inorganic second barrier layer.

3. The thin film barrier of claim 1, wherein the thickness of the first hybrid barrier is 0.05-10 μm.

4. The thin film barrier of claim 1, wherein the thickness of the inorganic second barrier layer is 5-1000 nm.

5. The thin film barrier of claim 1, wherein the thickness of the inorganic second barrier layer is 2-20,000 nm.

6. The thin film barrier of claim 1, wherein the inorganic layer comprises a material selected from the group consisting of: a metal, a metal oxide, a metal nitride, a metal oxy-nitride, a metal carbide, a metal boride, and a metal oxy-boride.

7. (canceled)

8. The thin film barrier of claim 1, wherein the inorganic layer comprises a material selected from the group consisting of: silicon oxide, aluminum oxide, indium oxide, tin oxide, zinc oxide, indium tin oxide, indium zinc oxide, aluminum zinc oxide, tantalum oxide, zirconium oxide, niobium oxide, and molybdenum oxide.

9. The thin film barrier of claim 1, wherein the inorganic layer comprises a material selected from the group consisting of: silicon nitride, aluminum nitride, boron nitride, tungsten carbide, boron carbide, silicon carbide, zirconium oxyboride, titanium oxyboride, aluminum oxynitride, silicon oxynitride, and boron oxynitride.

10-12. (canceled)

13. The thin film barrier of claim 1, wherein the hybrid barrier layer has a diffusion coefficient of water vapor of less than 10⁻⁹ cm²/sec at 38 C.

14. The thin film barrier of claim 1, wherein the thin film barrier is flexible.

15. An organic light emitting device (OLED) comprising a thin film barrier as recited in claim 1.

16. The device of claim 15, wherein the thin film barrier extends not more than 0.01-10 mm beyond the edge of the OLED.

17. The device of claim 15, wherein the OLED is a flexible OLED, and wherein the thin film barrier is flexible.

18. A method comprising:
obtaining at least one precursor, the at least one precursor comprising at least one organosilicon precursor;
plasma depositing each of the at least one precursors to form a barrier layer comprising SiOₓC_{y}H_{z} above a substrate; and
depositing an inorganic layer above the substrate, immediately adjacent to the barrier layer.

19. The method of claim 18, wherein the barrier layer is disposed between the substrate and the inorganic layer.

20. The method of claim 18, wherein each of the barrier layer and the inorganic layer is deposited without the use of masks.

21. The method of claim 18, wherein each of the barrier layer and the inorganic layer is deposited through as a minimum of one mask.

22. The method of claim 18, wherein the barrier layer and the inorganic layer are deposited through a single common mask.

23. The method of claim 18, wherein the at least one precursor comprises Si, O, C, and H.

24. The method of claim 18, wherein each of the at least one precursors is deposited in a single plasma deposition process.

25-29. (canceled)
